(19) United States
(12) Patent Application Publication
(10) Pub. No.: US 2015/0102349 A1
(43) Pub. Date: Apr. 16, 2015

(54) THIN FILM TRANSISTOR ARRAY SUBSTRATE AND MANUFACTURING METHOD THEREOF

(71) Applicant: SAMSUNG DISPLAY CO., LTD., Yongin-City (KR)

(72) Inventors: Wang-Woo Lee, Yongin-City (KR); Moo-Soon Ko, Yongin-City (KR); Do-Hyung Kim, Yongin-City (KR); Min-Woo Woo, Yongin-City (KR); Il-Jeong Lee, Yongin-City (KR); Jeong-Ho Lee, Yongin-City (KR); Young-Woo Park, Yongin-City (KR)

(73) Assignee: SAMSUNG DISPLAY CO., LTD., Yongin-City (KR)

(21) Appl. No.: 14/242,672

(22) Filed: Apr. 1, 2014

(30) Foreign Application Priority Data
Oct. 16, 2013 (KR) 10-2013-0123594

(51) Int. Cl. H01L 27/12

(52) U.S. Cl. CPC H01L 27/1255; H01L 27/1288; H01L 27/1251
USPC 257/71; 438/155

(57) ABSTRACT

A thin film transistor array substrate including a first TFT including a first active layer, a gate electrode, a first source electrode and a first drain electrode, a second TFT including a second active layer, a floating gate electrode, a control gate electrode, a second source electrode, and a second drain electrode, a capacitor including a first electrode and a second electrode, and a capping layer contacting a portion of the first electrode, the capping layer and the second electrode being on a same layer, is disclosed. A method of manufacturing thin film transistor array substrate is also disclosed.

### CROSS-REFERENCE TO RELATED APPLICATION

This application claims priority to and the benefit of Korean Patent Application No. 10-2013-0123594, filed on Oct. 16, 2013, in the Korean Intellectual Property Office, the entire content of which is incorporated herein by reference.

### BACKGROUND

1. Field

One or more aspects of embodiments of the present disclosure relate to a thin film transistor array substrate and a manufacturing method thereof.

2. Description of the Related Art

Display apparatuses are apparatuses for displaying images. Recently, organic light-emitting display apparatuses have attracted attention.

Organic light emitting display apparatuses have self light emitting characteristics and do not require separate light sources, which are different from liquid crystal display devices that require a separate light source. Accordingly, thickness and weight of an organic light-emitting display apparatus may be reduced as compared to a liquid crystal display device. Also, organic light-emitting display apparatuses exhibit high definition characteristics, such as low power consumption, high brightness, and a high reaction speed.

### SUMMARY

One or more aspects of embodiments of the present disclosure are directed toward a thin film transistor array substrate on which a high resolution display apparatus may be implemented.

Additional aspects will be set forth in part in the description which follows and, in part, will be apparent from the description, or may be learned by practice of the presented embodiments.

According to one or more embodiments of the present disclosure, a thin film transistor (TFT) array substrate includes: a first TFT including a first active layer, a gate electrode, a first source electrode and a first drain electrode; a second TFT including a second active layer, a floating gate electrode, a control gate electrode, a second source electrode, and a second drain electrode; a capacitor including a first electrode and a top electrode; and a capping layer contacting a portion of the first electrode, the capping layer and the top electrode being on a same layer.

The TFT array substrate may further include: a first insulating layer between the first active layer and the gate electrode, and between the second active layer and the floating gate electrode; and a second insulating layer between the floating gate electrode and the control gate electrode.

The first electrode of the capacitor and the gate electrode may be on a same layer, and the top electrode of the capacitor and the control gate electrode may be on a same layer.

The first electrode may include a low resistivity material.

The low resistivity material may include an aluminum alloy.

The capping layer may include molybdenum.

The second insulating layer may be between the first and second electrodes of the capacitor, and the capping layer may be electrically connected to the first electrode through a contact hole in the second insulating layer.

The first and second insulating layers may each include an inorganic insulating material

A high permittivity material may be included in at least a portion between the first and second electrodes of the capacitor.

The TFT array substrate may further include a connection interconnection layer electrically connected through the capping layer and a contact hole.

According to one or more embodiments of the present disclosure, a method of manufacturing a TFT array substrate, includes: forming a first active layer of a first TFT and a second active layer of a second TFT; forming a gate electrode on the first active layer, a floating gate electrode on the second active layer, and a first electrode of a capacitor; and forming a control gate electrode on the floating gate electrode, a top electrode on the first electrode, and a capping layer contacting a portion of the first electrode.

The manufacturing method may further include: forming a first insulating layer between the first active layer and the gate electrode, and between the second active layer and the floating gate electrode; and forming a second insulating layer between the floating gate electrode and the control gate electrode.

The manufacturing method may further include doping and heat-treating the first and second active layers between the forming of the gate electrode and the floating gate electrode, and the forming of the control gate electrode.

The first electrode may include a low resistivity material, and the low resistivity material may include an aluminum alloy.

The capping layer may include molybdenum.

The forming of the second insulating layer may include forming the second insulating layer between the bottom and top electrodes of the capacitor, and the forming of the capping layer may include: forming a contact hole in the second insulating layer exposing a portion of the first electrode; and forming the capping layer electrically connected to the first electrode through the contact hole formed in the second insulating layer.

The manufacturing method may further include: forming a third insulating layer on the capping layer; forming a contact hole in the third insulating layer exposing a portion of the capping layer; and forming a connection wiring electrically connected to the capping layer through the contact hole.

The forming of the contact hole may include: coating a photoresist material on the third insulating layer; dry-etching the photoresist material to form the contact hole; and cleaning the contact hole.

The forming of the contact hole exposing a portion of the first electrode may further include forming an aperture in the second insulating layer exposing a portion of the first electrode, and forming a high permittivity material layer in the aperture before the forming of the capping layer.

### BRIEF DESCRIPTION OF THE DRAWINGS

These and/or other aspects will become apparent and more readily appreciated by reference to the following description when considered together with the accompanying drawings in which:

FIG. 1 is an equivalent circuit diagram for a pixel of a display apparatus according to an embodiment of the present disclosure;

FIG. 2 is a schematic plan view illustrating a pixel of FIG. 1 according to an embodiment of the present disclosure;

FIG. 3 is a schematic cross-sectional view of the thin film transistor array substrate of FIG. 2 taken along lines A-A′ and B-B′;

FIG. 4 is a flowchart schematically illustrating a manufacturing process of a thin film transistor array substrate according to an embodiment of the present disclosure;

FIGS. 5 to 9 are cross-sectional views schematically illustrating the manufacturing process of the thin film transistor array substrate shown in FIG. 2;

FIG. 10 is a graph illustrating a change of resistivity according to doping and heat treatment; and

FIG. 11 is a cross-sectional view schematically illustrating a thin film transistor array substrate according to another embodiment of the present disclosure.

### DETAILED DESCRIPTION

Reference will now be made to certain embodiments, examples of which are illustrated in the accompanying drawings, where like reference numerals refer to like elements throughout, and some duplicative explanations are not provided. As those skilled in the art would recognize, the described embodiments may be modified in many ways and may have different forms and should not be construed as being limiting. Accordingly, the embodiments are described below, by referring to the figures, merely to explain aspects of the present description.

It will be understood that although the terms “first”, “second”, etc. may be used herein to describe various components, these components should not be limited by these terms. These terms are only used to distinguish one component from another. As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “on” or “formed on,” another layer, region, or component, it can be directly on the other layer, region, or component, or indirectly on or formed on the other layer, region, or component with one or more intervening elements therebetween. For example, intervening layers, regions, or components may be present.

Sizes of elements in the drawings may be exaggerated for convenience of explanation. In other words, because sizes and thicknesses of components in the drawings may be arbitrarily illustrated for convenience of explanation, the following embodiments are not limited thereto.

When a certain embodiment may be implemented differently, a specific process order may be performed differently from the described order. For example, two consecutively described processes may be performed at the same time (or substantially at the same time) or performed in an order opposite to the described order.

As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the present disclosure refers to “one or more embodiments of the present disclosure.”

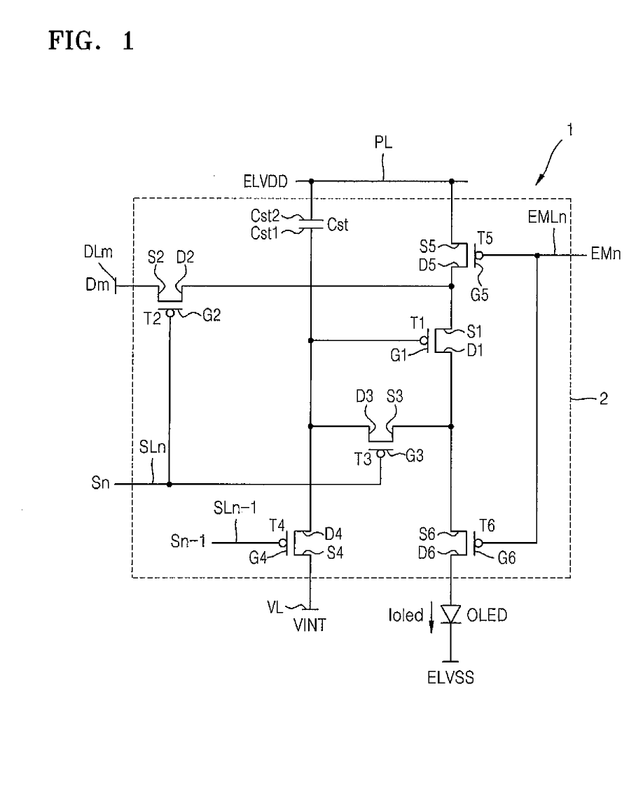

FIG. 1 is an equivalent circuit diagram for a pixel of a display device according to an embodiment of the present disclosure;

A pixel 1 of a display apparatus according to an embodiment of the present disclosure includes a pixel circuit 2 including a plurality of thin film transistors (TFTs) T1 to T6 and a storage capacitor Cst. The pixel 1 also includes an organic light emitting diode (OLED) which receives a driving current through the pixel circuit 2 and emits light.

The plurality of TFTs T1 to T6 are first to sixth TFTs.

The pixel 1 includes a first scan line SLn delivering a first scan signal Sn to the second and third TFTs T2 and T3, and a second scan line SLn−1 delivering a second scan signal Sn−1, which is a previous scan signal, to the fourth TFT T4. The pixel 1 further includes an emission control line EMLn delivering an emission control signal EMn to the fifth and sixth TFTs T5 and T6, and a data line DLm intersecting with the first scan line SLn and delivering a data signal Dm. The pixel 1 also further includes a driving voltage line PL formed almost in parallel (or substantially in parallel) with the data line DLm and delivering a first supply voltage ELVDD, and an initialization voltage line VL delivering an initialization voltage VINT for initializing the first TFT T1.

A gate electrode G1 of the first TFT T1 is connected to a first electrode Cst1 of the capacitor Cst. A source electrode S1 of the first TFT T1 is connected to the driving voltage line PL via the fifth TFT T5. A drain electrode D1 of the first TFT T1 is electrically connected to the anode electrode of the OLED via the sixth TFT T6. The first TFT T1 receives the data signal Dm according to a switching operation of the second TFT T2 to provide a driving current loled to the OLED.

A gate electrode G2 of the second TFT T2 is connected to the first scan line SLn. A source electrode S2 of the second TFT T2 is connected to the data line DLm. A drain electrode D2 of the second TFT T2 is connected to the source electrode S1 of the first TFT T1, and connected to the driving voltage line PL via the fifth TFT T5. The second TFT T2 is turned on according to the first scan signal Sn which is received through the first scan line SLn and performs a switching operation which delivers the data signal Dm received through the data line DLm to the source electrode S1 of the first TFT T1.

A gate electrode G3 of the third TFT T3 is connected to the first scan line SLn. A source electrode S3 of the third TFT T3 is connected to the drain electrode D1 of the first TFT T1 and is connected to the anode electrode of the OLED via the sixth TFT T6. A drain electrode D3 of the third TFT T3 is connected together to a first electrode Cst1 of the capacitor Cst, a drain electrode D4 of the fourth TFT T4, and the gate electrode G1 of the first TFT T1. The third TFT T3 is turned on according to the first scan signal Sn, which is received through the first scan line SLn, to diode-connect the first TFT T1 by connecting the gate electrode G1 and the drain electrode D1 of the first TFT T1 via the third TFT T3.

A gate electrode G4 of the fourth TFT T4 is connected to the second scan line SLn−1. A source electrode S4 of the fourth TFT T4 is connected to the initialization voltage line VL. The drain electrode D4 of the fourth TFT T4 is connected together to the first electrode Cst1 of the capacitor Cst, the drain electrode D3 of the third TFT T3, and the gate electrode G1 of the first TFT T1. The fourth TFT T4 is turned on according to the second scan signal Sn−1, which is received through the second scan line SLn−1, and, when turned on, initializes a voltage of the gate electrode G1 of the first TFT T1 by delivering the initialization voltage VINT to the gate electrode G1 of the first TFT T1.

A gate electrode G5 of the fifth TFT T5 is connected to the emission control line EMLn. A source electrode S5 of the fifth TFT T5 is connected to the driving voltage line PL. A drain electrode D5 of the fifth TFT T5 is connected to the source electrode S1 of the first TFT T1 and the drain electrode D2 of the second TFT T2.

A gate electrode G6 of the sixth TFT T6 is connected to the emission control line EMLn. A source electrode S6 of the sixth TFT T6 is connected to the drain electrode D1 of the first TFT T1 and the source electrode S3 of the third TFT T3. A drain electrode D6 of the sixth TFT T6 is electrically connected to the anode electrode of the OLED. The fifth and sixth TFTs T5 and T6 are simultaneously (or concurrently) turned on according to the emission control signal EMn, which is received through the emission control line EMLn, and, when turned on, deliver the first supply voltage ELVDD to the OLED. Then, the driving current loled flows to the OLED.

A second electrode Cst 2 of the capacitor Cst is connected to the driving voltage line PL. The first electrode Cst1 is connected together to the gate electrode G1 of the first TFT T1, the drain electrode D3 of the third TFT T3, and the drain electrode D4 of the fourth TFT T4.

The cathode electrode of the OLED is connected to a second supply voltage ELVSS. The OLED displays an image by receiving the driving current loled from the first TFT T1 and emitting a light.

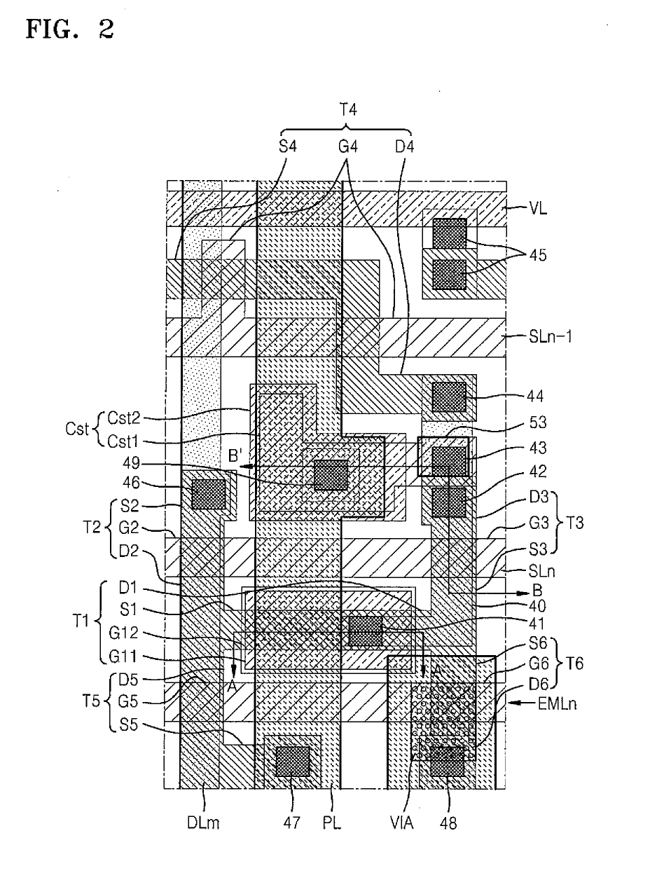

FIG. 2 is a schematic plan view of the pixel of FIG. 1 according to an embodiment of the present disclosure.

As shown in FIG. 2, the pixel 1 of the display apparatus according to an embodiment of the present disclosure includes the first scan line SLn, the second scan line SLn−1, the emission control line EMLn, and the initialization voltage line VL which are extend along a horizontal direction and apply (e.g., supply) the first scan signal Sn, the second scan signal Sn−1, the emission control signal EMn, and the initialization voltage VINT, respectively, to the pixel 1. In FIG. 2, the pixel 1 also includes the data line DLm and the driving voltage line PL which intersect with each of the first scan line SLn, the second scan line SLn−1, the emission control line EMLn, and the initialization voltage line VL. The data line DLm and the driving voltage line PL apply (e.g., supply) the data signal Dm and the first supply voltage ELVDD, respectively, to the pixel 1.

In this embodiment, the first scan line SLn, the second scan line SLn−1, the emission control line EMLn, the first electrode Cst1 of the capacitor Cst, a floating gate electrode (e.g., a second gate electrode) of the first TFT T1 are formed from the same (or substantially the same) first conductive material on the same layer. The second electrode Cst2 of the capacitor Cst, the gate electrode G1 (e.g., a first gate electrode) of the first TFT T1, a capping layer of the capacitor Cst are formed from the same (or substantially the same) second conductive material on the same layer.

Wiring formed from the first conductive material and wiring formed from the second conductive material are on different layers (e.g., distinct layers) with an insulating layer therebetween. Distances between neighboring wirings positioned on the different layers may be narrower as compared to other neighboring wirings which are positioned on the same layer. Accordingly, a larger number of pixels may be formed on the same area as compared to with other wiring. For example, a high resolution display apparatus may be formed using (utilizing) embodiments of the present disclosure.

The pixel 1 according to an embodiment of the disclosure has the first to sixth TFTs T1 to T6 and the capacitor Cst formed therein. The OLED may be at a region corresponding to a via hole VIA.

As shown in FIG. 2, the first TFT T1 includes a first gate electrode G11, which is a control electrode, a second gate electrode G12, which is a floating electrode, a source electrode S1 and a drain electrode D1. The source electrode S1 corresponds to a source region into which impurities are doped in a semiconductor layer, and the drain electrode D1 corresponds to a drain region into which impurities are doped in the semiconductor layer. The first gate electrode G11 is connected to the first electrode Cst1 of the capacitor Cst, the drain electrode D3 of the third TFT T3, and the drain electrode D4 of the fourth TFT T4 by a connection member 40 through contact holes 41 to 44.

The second TFT T2 includes the gate electrode G2, the source electrode S2, and the drain electrode D2. The source electrode S2 corresponds to a source region into which impurities are doped in a semiconductor layer, and the drain electrode D2 corresponds to a drain region in which impurities are doped in the semiconductor layer. The source electrode S2 is connected to a data line DLm through a contact hole 46. The drain electrode D2 is connected to the source electrode S1 of the first TFT T1 and the drain electrode D5 of the fifth TFT T5. The gate electrode G2 is formed by (or corresponds to) a portion of the first scan line SLn.

The third TFT T3 includes the gate electrode G3, the source electrode S3, and the drain electrode D3. The source electrode S3 corresponds to a source region in which impurities are doped in a semiconductor layer, and the drain electrode D3 corresponds to a drain region into which impurities are doped in the semiconductor layer. The gate electrode G3 is formed by (or corresponds to) a portion of the first scan line SLn.

The fourth TFT T4 includes the gate electrode G4, the source electrode S4, and the drain electrode D4. The source electrode S4 corresponds to a source region in which impurities are doped in a semiconductor layer, and the drain electrode D4 corresponds to a drain region into which impurities are doped in the semiconductor layer. The source electrode S4 may be connected to the initialization voltage line VL through a contact hole 45 (at the left of FIG. 2). The gate electrode G4 is formed of dual gate electrodes by (or corresponding to) a portion of the second scan line SLn−1 and prevents (or reduces) a leakage current.

The fifth TFT T5 includes the gate electrode G5, the source electrode S5, and the drain electrode D5. The source electrode S5 corresponds to a source region in which impurities are doped in a semiconductor layer, and the drain electrode D5 corresponds to a drain region into which impurities are doped in the semiconductor layer. The source electrode S5 may be connected to the driving voltage line PL through a contact hole 47. The gate electrode G5 is formed by a portion of the emission control line EMLn.

The sixth TFT T6 includes the gate electrode G6, the source electrode S6, and the drain electrode D6. The source electrode S6 corresponds to a source region in which impurities are doped in a semiconductor layer, and the drain electrode D6 corresponds to a drain region into which impurities are doped in the semiconductor layer. The drain electrode D6 is connected to the anode electrode of the OLED through the via hole VIA connected to a contact hole 48. The gate electrode G6 is formed by (or corresponds to) a portion of the emission control line EMLn.

The first electrode Cst1 of the capacitor Cst is connected to the capping layer 53 on a top surface thereof, and the capping layer 53 is connected together to the drain electrode D3 of the third TFT T3, the drain electrode D4 of the fourth TFT T4, and the first gate electrode G11 of the first TFT T1 by the connection member 40 through the contact hole 43. The connection member 40 is on (e.g., formed on) the same layer as that of the data line DLm.

The second electrode Cst2 of the capacitor Cst is connected to the driving voltage line PL through a contact hole 49 and receives the first supply voltage ELVDD from the driving voltage line PL.

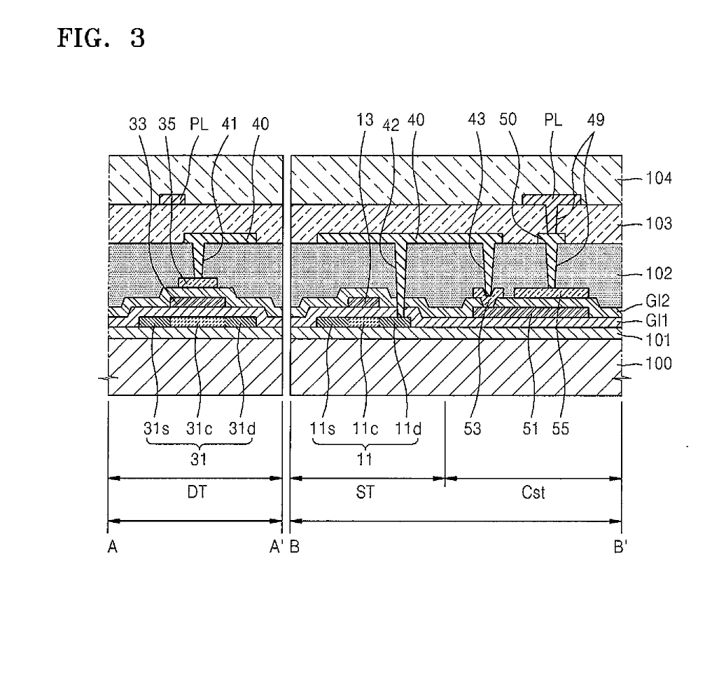

FIG. 3 is a schematic cross-sectional view of the TFT array substrate of FIG. 2 taken along lines A-A′ and B-B′.

The TFT array substrate includes a plurality of scan lines SLn and SLn−1, and a plurality of data lines DLm in a plurality of pixels 1. An array of a TFT, a light emitting device, and a capacitor included in each of the plurality of pixels 1 is referred to as a TFT array.

A TFT array substrate 100 may include first to sixth TFTs T1 to T6, and a capacitor Cst. Hereinafter, the first TFT T1 is represented (or referred to) as a driving TFT DT, and the second to sixth TFTs T2 to T6 are represented (or referred to) as switching TFTs ST. For convenience, FIG. 3 shows the driving TFT DT corresponding to the first TFT T1 and the switching TFT ST corresponding to the third TFT T3 among the second to sixth TFTs T2 to T6, and the capacitor Cst.

The driving TFT DT may include an active layer 31, which is a semiconductor layer, a floating gate electrode 33 corresponding to the second gate electrode G12 of the first TFT T1, a control gate electrode 35 corresponding to the first gate electrode G11, and source/drain electrodes 31s/31d corresponding to the source/drain electrodes S1/D1. A first insulating layer Gl1 may be between the active layer 31 and the floating gate electrode 33 of the driving TFT DT, and a second insulating layer Gl2 may be between the floating gate electrode 33 and the control gate electrode 35. Source/drain regions into which impurities are doped are on (e.g., formed on) both edges of the active layer 31 and function as the source/drain electrodes 31s/31d. The floating gate electrode 33 may include (e.g., be formed of) a single layer or a plurality of layers including a low resistive material (e.g., a low resistivity material). The control gate electrode 35 is formed from a material different from that of the floating gate electrode 33, and may include (e.g., be formed of) a single layer or a plurality of layers including materials having excellent heat resistance or chemical resistance.

The switching TFT ST may include an active layer 11, which is a semiconductor layer, a gate electrode 13 corresponding to the gate electrode G3 of the third TFT T3, and source/drain electrodes 11s/11d corresponding to the source/drain electrodes S3/D3. The first insulating layer Gl1 may be between the active layer 11 and the gate electrode 13 of the switching TFT ST. Source/drain regions into which impurities are doped are on (e.g., formed on) both edges of the active layer 11 and function as source/drain electrodes 11s/11d. The gate electrode 13 may include (e.g., be formed of) a single layer including a low resistive material (e.g., a low resistivity material) or a plurality of layers including the low resistive material (e.g., the low resistivity material).

The capacitor Cst includes (e.g., is formed of) a first electrode (e.g., a bottom electrode) 51 and a second electrode (e.g., a top electrode) 55 corresponding to the first and second electrodes Cst1 and Cst2, respectively, and includes the second insulating layer Gl2 therebetween. The bottom electrode 51 may be on (e.g., formed on) the same layer as those of the gate electrode 13 of the switching TFT ST and the floating gate electrode 33 of the driving TFT DT. The bottom electrode 51 may include (e.g., be formed of) a single layer or a plurality of layers including a low resistive material (e.g., a low resistivity material). The top electrode 55 may be on (e.g., formed on) the same layer as that of the control gate electrode 35 as the driving TFT DT. The top electrode 55 may be formed from a material different from that of the bottom electrode 51, and may include (e.g., be formed of) a single layer or a plurality of layers including materials having excellent heat resistance or chemical resistance. A portion of the bottom electrode 51 may contact the capping layer 53 to be electrically connected to the capping layer 53. The capping layer 53 may be formed from the same (or substantially the same) material as that of the top electrode 55 and be on the same layer. The capping layer 53 may be connected to connection member (wiring) 40, which may be on (e.g., formed on) a third insulating layer 102, through the contact hole 43. Thus, the bottom electrode 51 may be electrically connected to the drain electrode 11d of the switching TFT ST through the contact hole 42 via the connection member 40. In addition, the bottom electrode 51 is electrically connected to the control gate electrode 35 of the driving TFT DT through the connection member 40 and the contact hole 41. Furthermore, the capacitor Cst may include a high permittivity (high K) material, instead of the second insulating layer Gl2, between the bottom electrode 51 and the top electrode 55.

Fourth and fifth insulating layers 103 and 104 may be on (e.g., formed on) the driving TFT DT, the switching TFT ST, and the capacitor Cst. The driving voltage line PL, which is electrically connected to the top electrode 55 of the capacitor Cst through a contact hole 49, may be between the fourth and fifth insulating layers 103 and 104.

An OLED may be on the fifth insulating layer 104 at (or formed in) a region of the via hole VIA as shown in FIG. 2. The OLED includes a pixel electrode (an anode electrode), an opposite electrode (a cathode electrode) facing the pixel electrode, and an intermediate layer therebetween. The pixel electrode may be connected to one of the first to sixth TFTs T1 to T6. The intermediate layer includes an organic emission layer. As a non-limiting example, the intermediate layer includes the organic emission layer, and may further include at least one of a hole injection layer HIL, a hole transport layer HTL, an electron transport layer ETL, and an electron injection layer EIL. However, the present disclosure is not limited thereto, and the intermediate layer may include an organic emission layer, and further include other various functional layers. The opposite electrode may be on (e.g., formed on) an entire surface of the TFT array substrate 100 to function as a common electrode.

Furthermore, the source and drain electrodes of each of the first to sixth TFTs T1 to T6 according to an embodiment of the present disclosure are the source and drain regions into which impurities are doped, but the source and drain electrodes are not limited thereto. The source and drain electrodes of each of the first to sixth TFTs T1 to T6 according to another embodiment of the present disclosure may be connected to the source and drain regions on (or of) a layer different from the active layer.

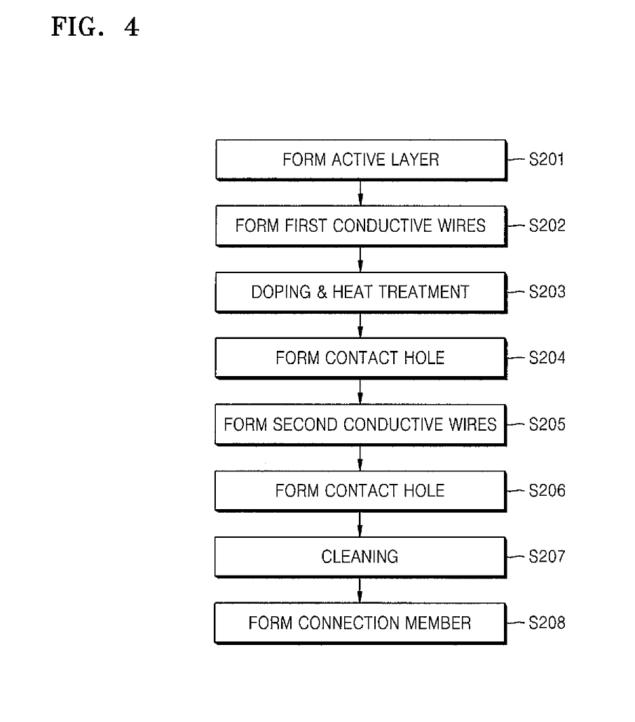

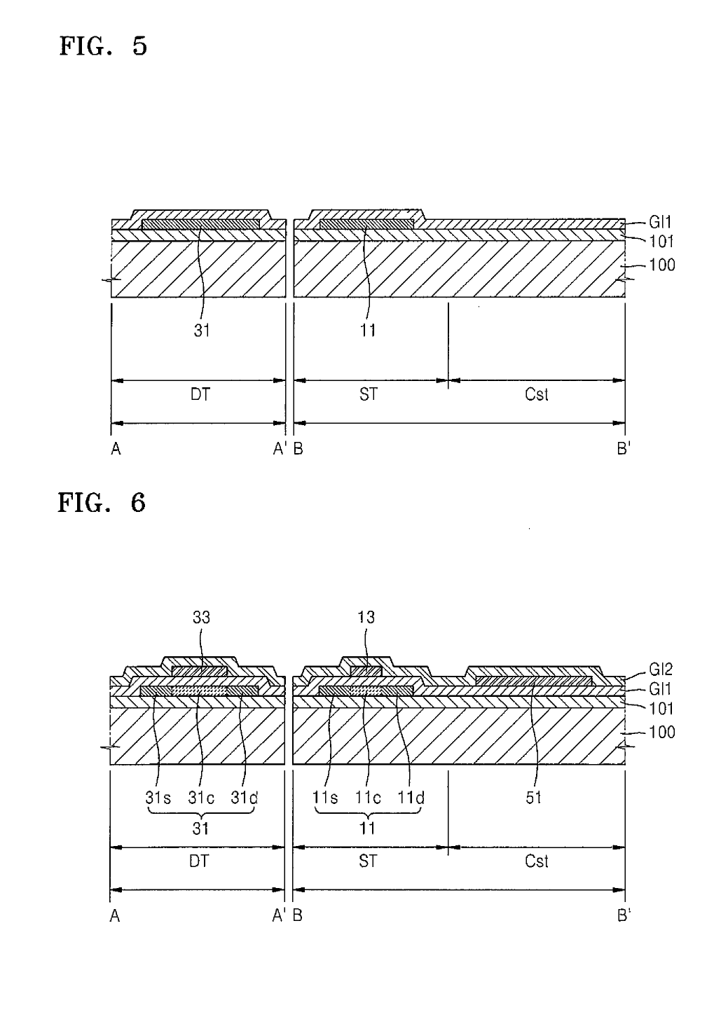

FIG. 4 is a flowchart schematically illustrating a manufacturing process of a TFT array substrate according to an embodiment of the present disclosure. FIGS. 5 to 9 are cross-sectional views schematically illustrating the manufacturing process of the TFT array substrate of FIG. 3. Hereinafter, the manufacturing process of the TFT array substrate shown in FIGS. 5 to 9 is schematically described.

Referring to FIGS. 4 and 5, the active layer 11 of the switching TFT ST and the active layer 31 of the driving TFT DT are formed on the TFT array substrate (hereinafter referred as ‘array substrate’) 100 (operation S201).

The array substrate 100 may be formed from a glass material of a transparent material having SiO₂ as a main component. However, the array substrate 100 is not limited thereto, and substrates of various materials, such as transparent plastics or metals, may be used (utilized).

An auxiliary layer 101 (also shown in FIG. 5), such as a barrier layer, a blocking layer, and/or a buffer layer may be formed on the array substrate 100, which prevents impurity ions from diffusing (or reduces such diffusion), prevents moisture or air from permeating (or reduces such permeation), and flattens the surface thereof. The auxiliary layer 101 may be formed by various suitable deposition methods using (utilizing) SiO₂ and/or SiNₓ. The auxiliary layer 101 may be omitted.

The active layer 11 of the switching TFT ST and the active layer 31 of the driving TFT DT are formed on the auxiliary layer 101. The active layers 11 and 31 may be formed by patterning an amorphous silicon layer. The active layers 11 and 31 may include a semiconductor or an oxide semiconductor.

The first insulating layer Gl1 is formed on the array substrate 100 on which the active layers 11 and 31 are formed. The first insulating layer Gl1 may include (e.g., be formed from) an inorganic insulating material selected from among SiO₂, SiNx, Al₂O₃, CuOx, Tb₄O₇, Y₂O₃, Nb₂O₅, and Pr₂O₃, or at least one organic insulating material selected from a group consisting of polyimide, polyamide, acrylic resin, benzocyclobutene, and phenol resin, or a multilayer structure where the insulating material and the inorganic insulating material are alternated.

Then, referring FIGS. 4 and 6, first conductive wiring is formed on the first insulating layer Gl1 (operation S202).

The first conductive wiring may include the gate electrode 13 of the switching TFT ST, the floating gate electrode 33 of the driving TFT DT, and the bottom electrode 51 of the capacitor Cst. The first conductive wiring may include (e.g., be formed of) a single layer including a low resistive metal material (e.g., a low resistivity material), such as aluminum (Al), aluminum-alloy (Al-alloy), or copper (Cu), or a structure having a plurality of layers including one or more metals selected from among platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), and tungsten (W). For example, the first conductive wiring may include (e.g., be formed of) a single layer of aluminum-alloy, or a structure of a plurality of layers of aluminum alloy/TiN, or TiN/aluminum-alloy/TIN.

In realizing a high resolution display, such as a display capable of full high-definition, or ultra high definition, low resistive wiring is suitable for reducing a scan delay.

When the first conductive wiring includes (or is formed from) aluminum alloy, such as AINd (e.g., an aluminum-neodymium alloy), having high thermal resistance, a problem, such as hillock (or growth that may result in shorts between levels), is prevented from occurring (or such occurrence is reduced) in (or during) heat treatment suitable for a low-temperature polycrystalline silicon (LIPS) process.

After forming the first conductive wiring, the active layers 11 and 31 are doped and heat-treated (operation S203).

In an embodiment of the present disclosure, the gate electrode 13 of the switching TFT ST and the floating gate electrode 33 of the driving TFT DT are formed together (e.g., concurrently or simultaneously), and then doping and heat treatment are performed for the active layers 11 and 31.

Performing doping and heat treatment for the active layer 11 and 31 after forming the capping layer 53 and the control gate electrode 35 of the driving TFT DT, which is described later, cause discoloration and increase in resistivity between the bottom substrate 51 of the capacitor Cst and the capping layer 53. In the embodiment of the present disclosure, doping and heat treatment are performed for the active layers 11 and 31 before forming the capping layer 53 and the control gate electrode 53 of the driving TFT DT, and thus such occurrence can be reduced.

On the other hand, the driving TFT DT includes the floating gate electrode 33 as (e.g. to be formed as) a nonvolatile memory device. Accordingly, the driving TFT DT stores (e.g., is capable of storing) a compensation value for a threshold voltage in the floating gate electrode 33 to compensate for the threshold voltage of the driving TFT DT.

N-type or p-type impurities are doped into the active layers 11 and 31 by utilizing the gate electrode 13 of the switching TFT ST and the floating gate electrode 33 of the driving TFT DT, respectively, as self aligning masks. Accordingly, the source/drain regions 11s/11d, with a channel region 11c (also shown in FIG. 3) therebetween, are formed at edges of the active layer 11 corresponding to two (e.g., both) sides of the gate electrode 13 of the switching TFT ST. The source/drain regions 11s/11d function as source/drain electrodes. In addition, the source/drain regions 31s/31d, with (also shown in FIG. 3) a channel region 31c therebetween, are formed at edges of the active layer 31 corresponding to two (e.g., both) sides of the floating gate electrode 33 of the driving TFT DT. The source/drain regions 11s/11d and 31s/31d may function as source/drain electrodes.

The active layers 11 and 31 may be formed as p-type layers when a III family element (e.g., a group III element), such as boron (B), is doped in the layers, and may be formed as n-type layers when a V family element (e.g., a group V element), such as nitrogen (N) is doped in the layers. In some embodiments, by doping at once, n-type or p-type impurities are injected into the bottom electrode 51 of the capacitor Cst, and the bottom electrode 51 of the capacitor Cst and the active layers 11 and 31 may be simultaneously (or concurrently) doped.

After doping the active layers 11 and 31, the amorphous silicon layer of the active layers 11 and 31 is crystallized to a crystalline silicon layer by heat-treating the active layers 11 and 31. The crystallization of the active layers 11 and 31 is performed by heat-treating at a temperature of about 580° C. or higher through various methods, such as a rapid thermal annealing (RTA) method, a solid phase crystallization (SPC) method, an excimer laser annealing (ELA) method, a metal induced crystallization (MIC) method, a metal induced lateral crystallization (MILC) method, a sequential lateral solidification (SLS) method, and/or an advanced sequential lateral solidification (ASLS) method, but the present disclosure is not limited thereto.

The bottom electrode 51 of the capacitor Cst may be subsequently electrically connected to the drain electrode of the switching TFT ST and the gate electrode of the driving TFT DT. For this, a contact hole is formed to expose a portion of the bottom electrode 51 of the capacitor Cst.

However, because the aluminum alloy has no (or substantially no or little) acid resistance to hydrogen fluoride or buffered oxide etchant (BOE), either of which is used (utilized), alone or in combination, in cleaning, the aluminum alloy may be damaged or etched (or completely etched) by the cleaning process. Accordingly, in an embodiment of the present disclosure, the capping layer is formed to protect the aluminum alloy, as described later.

FIG. 10 is a graph illustrating a resistivity change according to doping and heat treatment.

The left side of FIG. 10 is a graph illustrating a resistivity change according to doping and heat treatment for a single film (e.g., a single layer) of aluminum alloy. The right side of FIG. 10 is a graph illustrating a resistivity change according to doping and heat treatment for double films (e.g., a film including two layers) of aluminum alloy/molybdenum having molybdenum as a capping layer,

Referring to the left side graph of FIG. 10, resistivity (Rs) of the aluminum alloy single film becomes lowered as heat treatment temperature rises, after amorphous silicon deposition (AS-Depo) and doping are performed. On the other hand, referring to the right side graph of FIG. 10, resistivity (Rs) of the aluminum alloy/molybdenum double films becomes lowered as the temperature rises to 480° C., after the AS-Depo and doping are performed. And, then resistivity becomes higher as the temperature rises more, and discoloration and resistivity increase due to a reaction of the aluminum alloy and molybdenum at the heat treatment temperature of 580° C.

Accordingly, in an embodiment of the present disclosure, heat treatment is performed on a single film of the first conductive wiring, for example, an aluminum alloy single film, before forming the capping layer.

Then, the second insulating layer Gl2 is formed on the array substrate 100. The second insulating layer Gl2 may include (e.g., be formed from) an inorganic insulating material selected from among SiO₂, SiNx, Al₂O₃, CuOx, Tb₄O₇, Y₂O₃, Nb₂O₅, and Pr₂O₃, or at least one organic insulating material selected from a group consisting of polyimide, polyamide, acrylic resin, benzocyclobutene, and phenol resin, or a multilayer structure where the insulating material and the inorganic insulating material are alternated.

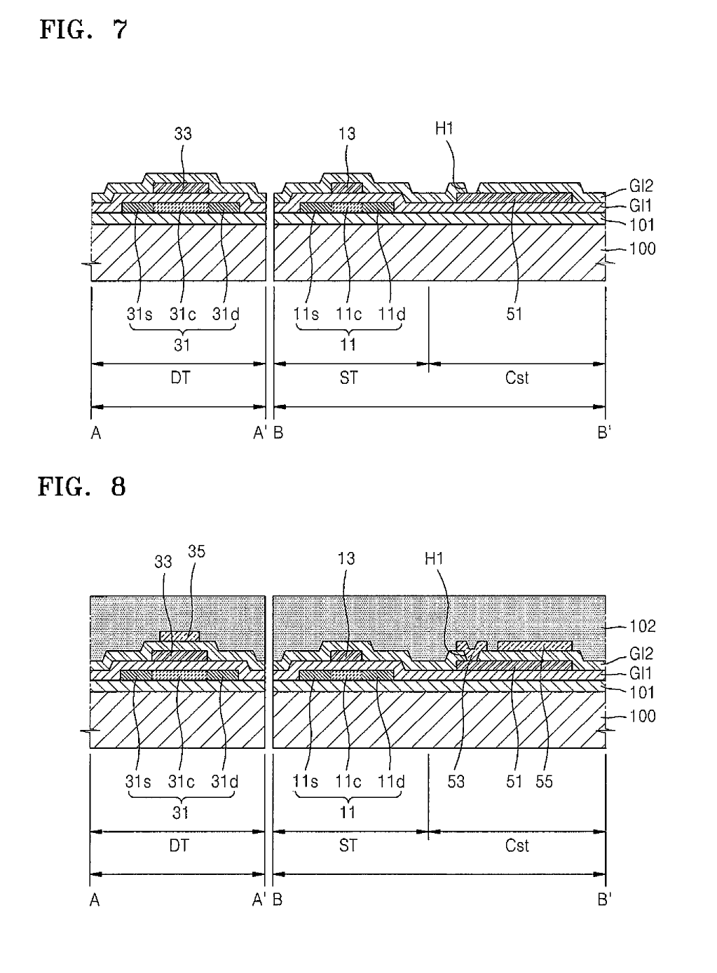

Then, referring to FIGS. 4 and 7, a contact hole H1 is formed in the second insulating layer Gl2, which exposes a portion of the bottom electrode 51 of the capacitor Cst (operation S204).

After uniformly coating a photoresist material on the entire second insulating layer Gl2, the contact hole H1 is formed through exposing via a mask (e.g., mask exposure), and a mask process of developing, etching, and stripping or ashing, but the present disclosure is not limited thereto. For example, the etching may be dry etching, but the present disclosure is not limited thereto.

Then, referring to FIGS. 4 and 8, second conductive wiring is formed on the second insulating layer Gl2 (operation S205).

The second conductive wiring may include the control gate electrode 35 of the driving TFT DT, the capping layer 53, and the top electrode 55 of the capacitor Cst. The second conductive wiring may be formed to include a structure of a single layer or a plurality of layers including one or more metals selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the second conductive wiring may be formed to include a structure of a single layer including molybdenum or a structure of a plurality of layers including aluminum alloy/molybdenum (e.g., an aluminum alloy layer and a molybdenum layer), or molybdenum/aluminum alloy/molybdenum (e.g., a first molybdenum layer, an aluminum alloy layer, and a second molybdenum layer).

In an embodiment of the present disclosure, in the driving TFT DT, an insulating layer between the active layer 31 and the control gate electrode 35 is formed to be thicker than an insulating layer between the active layer 11 and the gate electrode 13. For example, in the driving TFT DT, the first insulating layer Gl1 is between the active layer 31 and the floating gate electrode 33, and the second insulating layer Gl2 is between the floating gate electrode 33 and the control gate electrode 35. In the switching TFT ST, only the first insulating layer Gl1 is between the active layer 11 and the gate electrode 13.

When the driving TFT DT includes a thick gate insulating layer, and a light emitted from a light emitting device is represented as black and white according to a driving current flowing through the light emitting device, a driving range of a gate voltage Vgs, which is applied to the gate electrode of the driving TFT DT, becomes wider. For example, when the driving range of the driving TFT DT is wide, the light emitted from the light emitting device may be controlled to have rich gradation by differing (e.g., varying) a magnitude of the gate voltage Vgs applied to the gate electrode of the driving TFT DT.

As pixels per inch (PPI) of a display apparatus increases and a high resolution display apparatus is achieved, a high driving range is beneficial for the light emitted from the light emitting device to have rich gradation.

Accordingly, in an embodiment of the present disclosure, because the first and second insulating layers G11 and G12 are between the active layer 31 and the control gate electrode 35 of the driving TFT DT to form a thick insulating layer, the light emitting device is controlled to emit light having rich gradation. For example, according to embodiments of the present disclosure, a display apparatus is provided having high resolution as well as enhanced display quality.

The capping layer 53 fills the contact hole H1 and contacts the bottom electrode 51 of the capacitor Cst to be electrically connected to the bottom electrode 51, and is formed on the same layer as that of the top electrode 55 of the capacitor Cst. The capping layer 53 protects the bottom electrode 51 of the capacitor Cst, which includes (e.g., is formed with) low resistive wiring, from dry etching and cleaning.

Because the capping layer 53 may be damaged by dry etching when forming the contact hole thereafter, a metal having a proper selection ratio is favorable for the capping layer 53. As an example, molybdenum, which has excellent thermal resistance and chemical resistance, may be used (utilized) for the capping layer 53.

The capacitor Cst includes the bottom electrode 51 formed with first gate wiring and the top electrode 55 formed with second gate wiring. Accordingly, because the capacitor Cst does not need to have polycrystalline silicon having an non-uniform (e.g., an uneven) surface profile, storage capacity is not undesirably modified according to undesired modification of surface area of the electrode. For example, the capacitor Cst can store a precise storage capacity, which is initially designed (or set), and thus degradation of display quality is prevented (or such degradation is reduced) by precisely controlling the driving current, which is controlled by the driving TFT DT. For example, according to embodiments of the present disclosure, a display apparatus can be provided having high resolution as well as enhanced display quality.

In some embodiments, the capacitor Cst has a thin insulating layer by including, as the insulating layer, only the single second insulating layer Gl2 between the bottom electrode 51 and the top electrode 55 to enhance storage capacity.

The third insulating layer 102 is formed on the array substrate 100 on which the second conductive wiring is formed. The third insulating layer 102 is formed by a spin coating method with one or more organic insulating materials selected from a group consisting of polyimide, polyamide, acrylic resin, benzocyclobutene, and phenol resin, but the third insulating layer is not limited thereto. The third insulating layer 102 may be formed from not only an organic insulating material but also an inorganic insulating material selected from among SiO₂, SiNx, Al₂O₃, CuOx, Tb₄O₇, Y₂O₃, Nb₂O₅, and Pr₂O₃, but the third insulating layer is not limited thereto. Also, the third insulating layer 102 may be formed by alternating the organic insulating material and the inorganic insulating material.

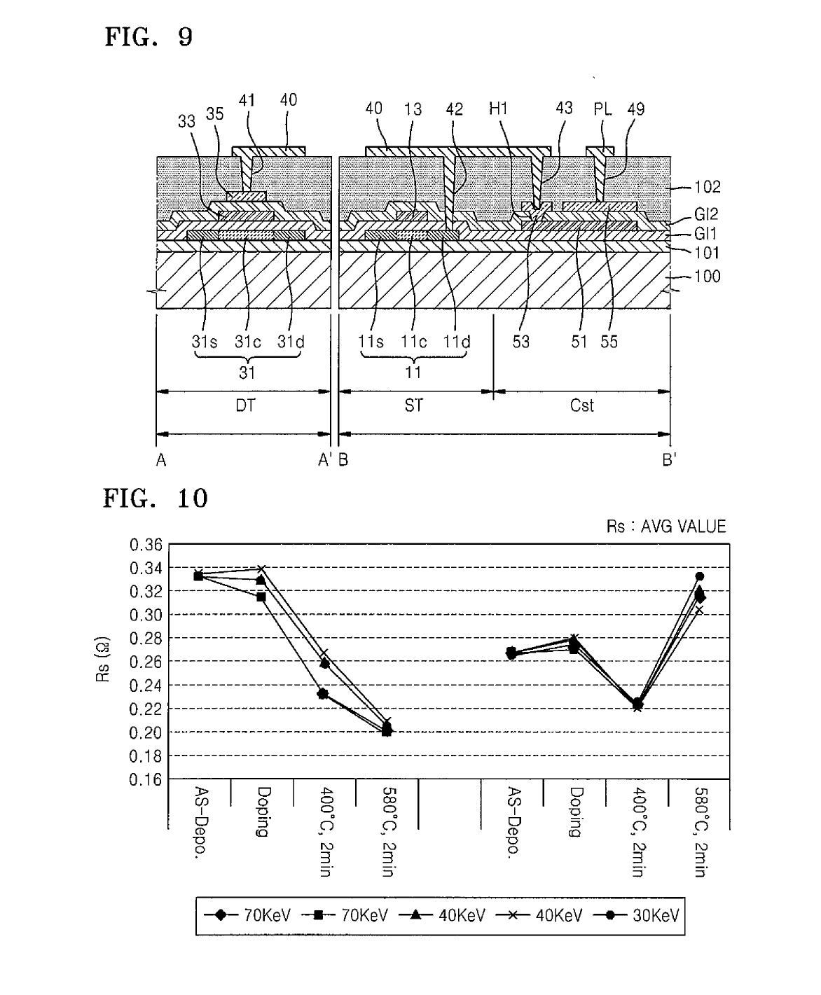

Then, referring to FIGS. 4 and 9, a plurality of contact holes 41, 42, 43, and 49 are formed in the third insulating layer 102 (operation S206). The contact holes 41, 42, 43, and 49 expose a portion of the control gate electrode 35 of the driving TFT DT, a portion of the drain region 11d of the switching TFT ST, a portion of the capping layer 53, and a portion of the top electrode 55 of the capacitor Cst, respectively.

The contact holes 41, 42, 43, and 49 may be formed by uniformly coating a photoresist material on the entire array substrate 100, exposing to a mask, and a mask process of developing, etching, and stripping or ashing, but the present disclosure is not limited thereto. For example, the etching may be dry etching.

The contact hole 42 may be formed by etching the first insulating layer Gl1, the second insulating layer Gl2, and the third insulating layer 102 at the same (or substantially the same) time with or after forming other contact holes 42, 43, and 49.

The contact holes 41, 42, 43, and 49 are cleaned by using (utilizing) hydrogen fluoride (HF) or buffered oxide etchant (BOE) (operation S207). For example, a natural oxide film formed by stacking inorganic layers on the active layer 11 may be removed by cleaning the contact hole 42 which exposes a portion of the drain region of the active layer 11.

Because the capping layer 53, the top electrode 55 of the capacitor Cst, and the control gate electrode 35 of the driving TFT DT exposed by the contact holes 41, 43, and 49 are formed from materials having excellent thermal resistance and chemical resistance, damage resulting from dry etching and cleaning is small (or negligible). In addition, the capping layer 53 may protect the bottom electrode 51 of the capacitor Cst from damage resulting from the dry etching and the cleaning.

Then, the connection member 40 is formed by filling the plurality of contact holes 41, 42, 43, and 49 on the third insulating layer 102 (operation S208). The connection member 40 may be formed to be a structure of a single layer or a plurality of layers including one or more materials selected from among Ag, Mg, Al, Pt, Pd, Au, Ni, Nd, Ir, Cr, Li, Ca, Mo, Ti, W, and Cu. The drain electrode 11d of the switching TFT ST, the control gate electrode 35 of the driving TFT DT, and the bottom electrode 51 of the capacitor Cst are electrically connected through the connection member 40.

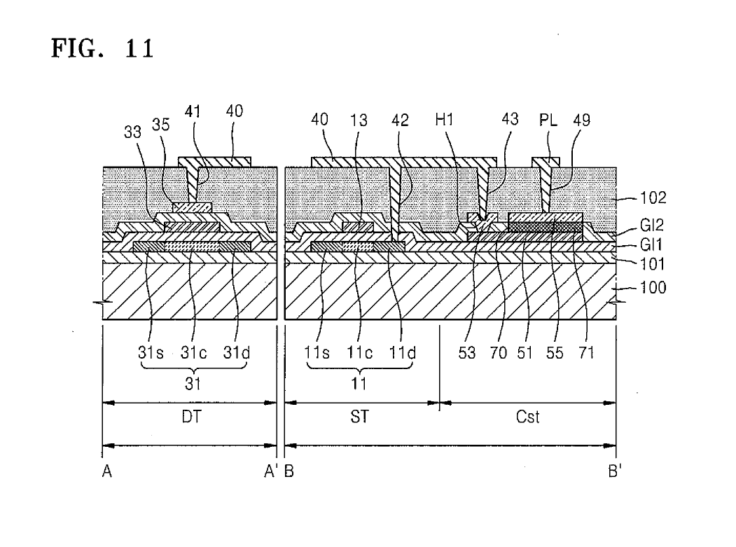

FIG. 11 is a schematic cross-sectional view of a TFT array substrate according to another embodiment of the present disclosure.

The embodiment shown in FIG. 11 is different from that shown in FIG. 9 in that a high permittivity (high K) material is between the bottom electrode 51 and the top electrode 55 of the capacitor Cst. The remaining features of FIG. 11 are the same (or substantially the same) as the corresponding features described above. Accordingly, duplicative descriptions of those features will not be provided here.

Referring to FIG. 11, the active layer 11 of the switching TFT ST and the active layer 31 of the driving TFT DT are on (e.g., formed on) the array substrate 100, and the first insulating layer Gl1 is on (e.g., formed on) the active layers 11 and 31. The auxiliary layer 101 may further be on (e.g., formed on) the array substrate 100.

Then, the first conductive wiring is on (e.g., formed on) the first insulating layer Gl1. The first conductive wiring may include the gate electrode 13 of the switching TFT ST, the floating gate electrode 33 of the driving TFT DT, and the bottom electrode 51 of the capacitor Cst. The first conductive wiring may be formed to be a structure of a single layer or a plurality of layers including a low resistive material (e.g., a low resistivity material), such as aluminum (Al), aluminum-alloy (Al-alloy) or copper (Cu), but the present disclosure is not limited thereto.

After forming the first conductive wiring, the active layers 11 and 31 are doped and heat-treated.

Then, the second insulating layer Gl2 is formed on the array substrate 100, and the contact hole H1 exposing a portion of the bottom electrode 51 of the capacitor Cst is formed in the second insulating layer Gl2. In addition, at the same (or substantially the same) time with or after forming the contact hole H1, an aperture 70, which exposes a portion of the bottom electrode 51 of the capacitor Cst, is formed by removing the second insulating layer Gl2 in a region corresponding to the top electrode 55.

Then, a high permittivity layer 71 is formed by depositing and patterning a high permittivity (high K) material, such as ZrO₂, HfO₃, and Y₂O₃, on the aperture 70 through a mask process, but the present disclosure is not limited thereto. The high permittivity layer 71 has no (or substantially no) change in device characteristics at high temperature in the heat treatment and may prevent (or reduce) current leakage. Accordingly, the characteristics of the capacitor Cst becomes excellent.

Then, the second conductive wiring is formed on the second insulating layer Gl2 and the high permittivity layer 71. The second conductive wiring may include the control gate electrode 35 of the driving TFT DT, the capping layer 53, and the top electrode 55 of the capacitor Cst. The second conductive wiring may be formed to have a structure of a single layer or a plurality of layers and to include one or more metals selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), but the present disclosure is not limited thereto.

Then, the third insulating layer 102 is formed on the array substrate 100 on which the second conductive wiring is formed. In addition, the plurality of contact holes 41, 42, 43, and 49 are formed in the third insulating layer 102, and cleaned. Then, the connection member 40 is formed by filling the plurality of contact holes 41, 42, 43, and 49 on the third insulating layer 102. The drain electrode 11d of the switching TFT ST, the control gate electrode 35 of the driving TFT DT, and the bottom electrode 51 of the capacitor Cst are electrically connected through the connection member 40.

The TFT array substrate according to the above described embodiments may minimize (or reduce) damage to the low resistive wiring due to processes of heat treatment, cleaning, and contact hole dry etching, which are suitable for forming the substrate by applying the low resistive wiring to provide a substrate suitable for a high resolution display apparatus, and forming the capping layer on the low resistive wiring.

The above described embodiments are not limited to the above described pixel structure, and may be applied to any suitable pixel structure to which the low resistive wiring is applied (or in which the low resistivity wiring is included). Each pixel may include a plurality of TFTs and one or more capacitors. The pixel may have further formed separate wiring and may be formed to have various structures by omitting existing wiring.

The TFT array substrate according to the above described embodiments is not limited to an OLED display apparatus including the above-described organic light-emitting devices, and can be applied to various display apparatuses including, for example, a liquid crystal display apparatus.

As described above, according to one or more aspects of the above embodiments of the present disclosure, a thin film transistor array substrate to which low resistance interconnections are applied and which is robust to heat treatment and cleaning can be manufactured.

It should be understood that the embodiments described herein should be considered in a descriptive sense only and not for purposes of limitation. Descriptions of features or aspects within each embodiment should typically be considered as available for other similar features or aspects in other embodiments.

While one or more embodiments of the present disclosure have been described with reference to the figures, it will be understood by those of ordinary skill in the art that various changes in form and details may be made therein without departing from the spirit and scope of the present disclosure as defined by the following claims, and equivalents thereof.

What is claimed is:

1. A thin film transistor (TFT) array substrate comprising:
a first TFT comprising a first active layer, a gate electrode, a first source electrode and a first drain electrode;
a second TFT comprising a second active layer, a floating gate electrode, a control gate electrode, a second source electrode, and a second drain electrode;
a capacitor comprising a first electrode and a second electrode; and
a capping layer contacting a portion of the first electrode, and the capping layer and the second electrode being on a same layer.

2. The TFT array substrate of claim 1, further comprising:
a first insulating layer between the first active layer and the gate electrode, and between the second active layer and the floating gate electrode; and
a second insulating layer between the floating gate electrode and the control gate electrode.

3. The TFT array substrate of claim 1, wherein the first electrode of the capacitor and the gate electrode are on a same layer, and the second electrode of the capacitor and the control gate electrode are on a same layer.

4. The TFT array substrate of claim 1, wherein the first electrode comprises a low resistivity material.

5. The TFT array substrate of claim 4, wherein the low resistivity material comprises an aluminum alloy.

6. The TFT array substrate of claim 1, wherein the capping layer comprises molybdenum.

7. The TFT array substrate of claim 2, wherein the second insulating layer is between the first and second electrodes of the capacitor, and the capping layer is electrically connected to the first electrode through a contact hole in the second insulating layer.

8. The TFT array substrate of claim 2, wherein the first and second insulating layers each comprise an inorganic insulating material.

9. The TFT array substrate of claim 7, further comprising a high permittivity material, in at least a portion between the first and second electrodes of the capacitor.

10. The TFT array substrate of claim 1, further comprising a connection member electrically connected to the capping layer through a contact hole.

11. A method of manufacturing a TFT array substrate, the method comprising:
forming a first active layer of a first TFT and a second active layer of a second TFT;
forming a gate electrode on the first active layer, a floating gate electrode on the second active layer, and a first electrode of a capacitor; and
forming a control gate electrode on the floating gate electrode, a second electrode on the first electrode, and a capping layer contacting a portion of the first electrode.

12. The method of claim 11, further comprising:
forming a first insulating layer between the first active layer and the gate electrode, and between the second active layer and the floating gate electrode; and
forming a second insulating layer between the floating gate electrode and the control gate electrode.

13. The method of claim 11, further comprising doping and heat-treating the first and second active layers between the forming of the gate electrode and the floating gate electrode, and the forming of the control gate electrode.

14. The method of claim 11, wherein the first electrode comprises a low resistivity material.

15. The method of claim 14, wherein the low resistivity material comprises an aluminum alloy.

16. The method of claim 11, wherein the capping layer comprises molybdenum.

17. The method of claim 12, wherein the forming of the second insulating layer comprises forming the second insulating layer between the first and second electrodes of the capacitor, and
the forming of the capping layer comprises:
forming a contact hole in the second insulating layer to expose a portion of the first electrode; and
forming the capping layer electrically connected to the first electrode through the contact hole formed in the second insulating layer.

18. The method of claim 11, further comprising:
forming a third insulating layer on the capping layer;
forming a contact hole in the third insulating layer to expose a portion of the capping layer; and
forming a connection member electrically connected to the capping layer through the contact hole.

19. The method of claim 18, wherein the forming of the contact hole comprises:
coating a photoresist material on the third insulating layer;
dry-etching the photoresist material to form the contact hole; and
cleaning the contact hole.

20. The method of claim 17, wherein the forming of the contact hole to expose the portion of the first electrode further comprises forming an aperture in the second insulating layer to expose the portion of the first electrode, and
forming a high permittivity material layer in the aperture before the forming of the capping layer.
